(19) United States
(12) Patent Application Publication
(10) Pub. No.: US 2024/0281360 A1
(43) Pub. Date: Aug. 22, 2024

(54) VERIFICATION SYSTEMS AND METHODS

(71) Applicant: Microsoft Technology Licensing, LLC, Redmond, WA (US)

(72) Inventor: Erik William BERG, Portland, OR (US)

(21) Appl. No.: 18/170,148

(22) Filed: Feb. 16, 2023

(51) Int. Cl. G06F 11/36

(52) U.S. Cl. CPC G06F 11/3616; G06F 11/362

(57) ABSTRACT

Embodiments of the present disclosure include techniques for verification of system designs. A debug tree includes nodes with corresponding parameter values. Nodes in the debug tree correspond to error events. Errors in the system may be searched against data sources to determine if an error has been previously observed. New nodes may be added by a user by specifying values of the parameters for particular nodes in the debug tree.

### BACKGROUND

The present disclosure relates generally to system design, and in particular, to verification systems and methods.

A wide variety of modern systems have an ever-increasing reliance on software in their design and use. Software (aka, computer code) is used for designing a wide range of systems, including software systems, electronic system, and even electronic circuits (e.g., using high level definition languages such as Verilog or very high level definition language, “VHDL”). Before program code can be deployed, it is typically necessary to verify that all the code works for its intended purposes. This is referred to as verification. Verification of system designs often requires debugging software issues (aka, bugs). However, for large complex systems, many different system designers may be employed to build the system. Accordingly, debugging expertise is often limited to the particular person or group of people responsible for particular areas of the system that are exhibiting errors.

The present disclosure includes techniques for verification and debugging of computer code.

### BRIEF DESCRIPTION OF THE DRAWINGS

FIG. 1 illustrates a verification system according to an embodiment.

FIG. 2 illustrates a verification method according to an embodiment.

FIG. 3 illustrates an example of node creation during debug according to an embodiment.

FIG. 4 illustrates another example of node creation during debug according to an embodiment.

FIG. 5 illustrates yet another example of node creation during debug according to an embodiment.

FIG. 6 depicts a simplified block diagram of an example computer system.

### DETAILED DESCRIPTION

Described herein are techniques for verification, including debug. In the following description, for purposes of explanation, numerous examples and specific details are set forth in order to provide a thorough understanding of some embodiments. Various embodiments as defined by the claims may include some or all of the features in these examples alone or in combination with other features described below and may further include modifications and equivalents of the features and concepts described herein.

Features and advantages of the present disclosure include innovative verification systems and methods. In some embodiments, the debug process can be represented as a decision tree connecting discrete observable events. The verification system may include a decision tree tool and data extraction modules. The decision tree tool represents error events as nodes in a debug tree. The data extraction modules handle data events that manifest as nodes in the debug tree. In one example embodiment, the data for the nodes may be represented as particular values for parameters (e.g., a parameter template) for different failure events. In one example application (e.g., electronic design automation, “EDA”), there may be three data types, unstructured, wave-based, and structured, which may be collapsed to unstructured and structured. Wave based may be combined into a structured data type, for example. The present techniques may provide code-free debug scripts useful for a wide range of verification contexts.

For example, a verification system may include separate software libraries defining the debug tree structure and software libraries for extracting node data, for example. Debug trees (aka, decision trees) build the context of a discrete system failure as the nodes are traversed and events are observed. In one example embodiment, debug tree nodes may be populated by three (3) types of nodes: root node, event definition nodes, and context check nodes. Accordingly, debug trees and the related parameter values may be used to create code-free debug collateral. Further examples and details of various embodiments are described below.

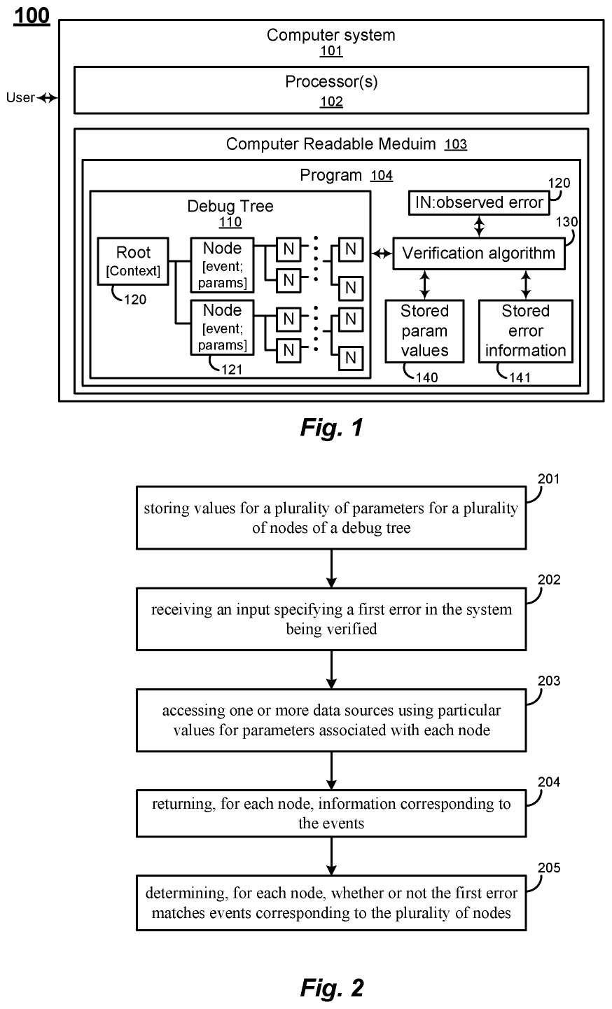

FIG. 1 illustrates a verification system according to an embodiment. Here, verification system 100 is implemented on a computer system 101 comprising one or more processors 102 and a non-transitory computer-readable medium 103 storing a program 104 executable by the one or more processors 102. The program comprising sets of instructions for performing the techniques described herein. Verification system 100 includes a debug tree 110. A debug tree comprises a root node 120 and a plurality of nodes associated to the root node directly or through one or more other nodes, which may form a tree-like structure between the root and nodes as illustrated in FIG. 1, for example. In some embodiments, the root node is associated with context for debug tree (e.g., the location of data sources storing error information) and the nodes may perform queries on the context based on the parameters. The root node may include custom code for performing debug relevant to a specific application, for example. The nodes correspond to particular observable events emitted by the system being verified or qualities of the context at that point in the decision tree execution. These error events may be stored electronically at 141 (e.g., in a memory or data store) so that when new errors occur a search may be conducted in the existing errors to determine which events occurred to cause the error. To effectuate such a search, the nodes have associated parameters and parameter values. The parameters may specify events defining electronically stored error events in a system being verified. Accordingly, when an observed error is analyzed, node parameter values may be used to determine if the observed error event matches one or more known events so the observed error event (or sequence of events) may be diagnosed quickly. Different nodes may have different values for different parameters. Some nodes may have the same parameters with different values, and some nodes may have different parameters in part or in total, for example. The values of the parameters may be stored at 140 (e.g., in memory or in a data store). In some embodiments described in more detail below, a set of parameters is presented to a user and the user specifies parameter values for at least a portion of the parameters to specify events that define the node.

Features and advantages of the present disclosure include analyzing newly observed errors to determine if the errors match nodes (e.g., a sequence of nodes) in the debug tree. If a newly observed error is completely characterized by nodes of the debug tree, the error can be identified quickly and easily by a user. If the error match some, but not all nodes of the debug tree, new nodes may be added to characterize the new error type for future reference. Accordingly, error information for system errors defining events and nodes of the debug tree are electronically stored at 141. Example error information may include log files or other software outputs or, for an electronic design automation system, waveform events or test bench outputs, for example.

When a newly observed error 120 in the system being verified is generated, verification algorithm 130 receives an input specifying the error 120. Verification algorithm 130 may retrieve a debug tree data structure and parameter values specifying the nodes of the debug tree as well as context for the root node. Verification algorithm may then access one or more data sources (e.g., used for storing error information 141) using particular values for parameters associated with each node. As mentioned above, the data sources may comprise information describing errors generated by the system being verified corresponding to the events for the plurality of nodes. The parameter values for each of the nodes may be used to search the stored error information to determine if the observed error 120 matches any of the stored error information, for example. The verification algorithm returns information corresponding to the events for each node. Next, the verification algorithm determines, for each node, whether or not the observed error 120 input into the verification algorithm matches any stored events corresponding to the plurality of nodes. An example output of the verification algorithm may comprise a list of nodes associated with true (the input error event matched a stored error event) or false (the input error event did not match a stored error event).

FIG. 2 illustrates a verification method according to an embodiment. At 201, values for a plurality of parameters for nodes of a debug tree are stored (e.g., in a data store). At 202, an input is received that specifies a first error in a system being verified. At 203, one or more data sources are accessed using particular values of the parameters associated with each node. At 204, information corresponding to the events is returned for each node. At 205, for each node, a determination is made for whether or not the first error matches events corresponding to the plurality of nodes. In one example embodiment, matches are designated as true and non-matches are designated as false.

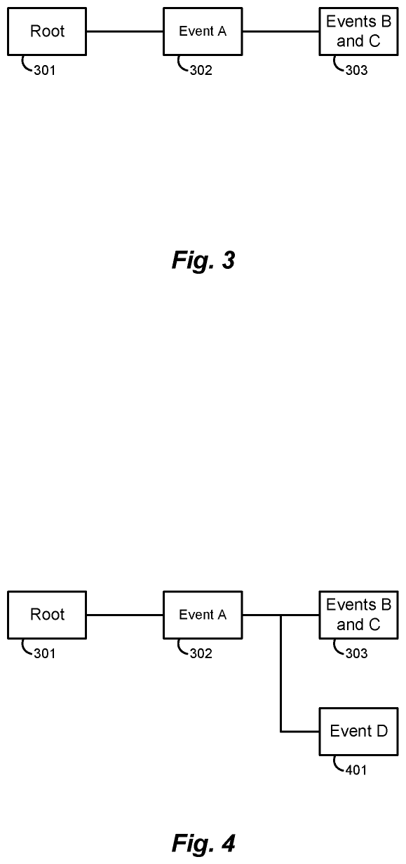

FIGS. 3-5 illustrate further example embodiments. While the techniques described in the present disclosure may be used for verification of a variety of computer code based systems, the following example illustrate verification in an electronic design automation (EDA) application.

FIG. 3 illustrates an example of node creation during debug according to an embodiment. A first failure is observed in the system being verified. In this example, debugging the failure determines that the root cause can be described by event A preceded by event B and event C. A user may create a debug tree starting with the root node 301. The user may create a node 302 directly coupled to root node 301, which corresponds to event A. The user may then create a node 303 directly coupled to node 302, which corresponds to events B and C.

Root node 301 may be associated with context, including log files, components of failure messages (e.g., address, time, failure type), test arguments, memory maps, a fast signal database (FSDB) of register transfer logic (RTL) signals (e.g., is a design abstraction in digital circuit design to model synchronous digital circuits in terms of the flow of digital signals (data) between hardware registers, and the logical operations performed on those signals), or other custom functions for the application, for example.

Next, the user may be prompted to enter parameter values for the node parameters for event A 302. In one embodiment, the same set of parameters may be used to characterize nodes. However, nodes of different types may use different parameters from the full parameter set. For example, nodes of structured data type (e.g., structured log files in CSV or JSON format) may have one set of common parameters and nodes of unstructured data type (e.g., free text) may have another set of common parameters. In one embodiment, parameters may include attributes for searching signals in an FSDB, for example. Events A is an event definition node, which defines observable (e.g., electronically recorded or stored) events to be extracted from available data sources. Observable events may be defined with the same parameters across the three data sources. Example node parameters may include some or all of the following:
1. Event definition: an arbitrary number of events to be observed as singular node. For free text data, event definition may be done by defining regular expression. For FSDB signal traces, event definition is performed on a tabular log file that is generated by extracting FSDB signal data for the set of signals required by the decision tree. For tabular structured log files, event definition is done using queries (e.g., a Python, SQL or another database query) on the structured data. Multiple events may be defined for a single node (e.g., events B and C 303 described below), in which case the relationship between the events is defined by an “event definition type”.
2. Event definition type: Defines relationships between component parameters of the node. In one example, the types may be {ANY, ALL, ORDERED}, which specifies the relationship between other parameters of the node to be satisfied. “ORDERED” may specify that a regular expression is to be followed by another regular expression (e.g., Regexp A followed by Regexp B). “ANY” refers to any ordering (e.g., Regexp A OR Regexp B). “ALL” in this example means all must be true (e.g., A AND B, without order.
3. Temporal relationship to other node(s): current node occurs at different times relative to previous node. For example, temporal relationships to other nodes may be defined using the following set: {FORWARD, BACKWARD, SAMETIME}. “FORWARD” indicates that the other node occurs after the current node, and the system should start the search for the other node forward in time. “BACKWARD” indicates that the other node occurs before the current node, and the system should start the search for the other node backward in time. “SAMETIME” indicates the other node occurs at the same time as the current node and the system should search accordingly. Stored error data is typically time stamped, which facilitates searching based on temporal relationships between adjacent nodes.
4. Start time: a previous node's “time” or an arbitrary value.
5. Time delta type: may be used to determine if the start time is the previous node time or the time of the first match when an event definition contains multiple entries (e.g., if there is a limit to the allowable temporal separation between events).
6. Time delta limit: amount of temporal separation can occur between nodes.
7. Instances to match: selects which instance of the event to observe (where the same event may happen more than once); if set to −1, then look for the last instance.
8. Stop search of regexp match: if found, stop the search for the entries in the event definition.
9. Ignore match groups: match groups in the event definition that may have values that should prevent a match.
10. Ignore values for match groups: values that should prevent a match for the specified group.′
11. Match groups to compare—Groups matched in the event definition to be compared.
12. Match group compare type—How the groups will be compared.
13. Return value if the event is not found—for negative testing; return True if the node evaluates to False.
14. Debug switch—Create high verbosity output to understand if/when a node is not behaving as expected.
15. Custom node output—Create a custom output message for the node

With the above example parameters, observable events can be defined for a wide range of debug scenarios. The parameters are used to used newly observed failure information to search stored observable events from prior failures to find matching events corresponding to known failure modes, which advantageously allows the user to debug code using a debug tree without writing additional source code.

In some embodiments, nodes may be designated as context check nodes. Context check nodes define nodes that evaluate context values (e.g., regular expressions in the parameters) against specific expected values supplied by the debug engineer. For example, context checks may be embedded in regular expressions and may check for specific values of one or more variables of a regular expression or other values making up an event node definition.

Referring again to FIG. 3, node 302 for event A may have the following example parameter values: [log file path: <path>; regular expression: <regular expression describing event A>; search direction: FORWARD; start time: “previous node time”; return value if regular expression not found: FALSE]. Similarly, node 302 for events B and C may have the following example parameter values: [log file path: <path>; regular expression 1: <regular expression describing event B>; regular expression 2: <regular expression describing event C>; regular expression match type: ALL; search direction: BACKWARD; start time: “previous node time”; return value if regular expression not found: FALSE].

FIG. 4 illustrates another example of node creation during debug according to an embodiment. FIG. 4 includes the occurrence of a newly observed test failure. The failure is debugged and it is determined that the root cause can be described by event A followed by event D. Accordingly, a new node 401 describing event D is added to the debug tree starting from node A. The parameters for node 401 may be: [log file path: <fsdb_log_path>; signal, value, bit range: “[signal, value]” (e.g., “[signal_for_event_D, “h5”]”); search direction: FORWARD; start time: “previous node time”; and return value if regular expression not found: FALSE]. As illustrated by the reference to an “fsdb_log_path” and “signal, value, bit range” parameter, node 401 for event D is based on a waveform event (e.g., a signal having one or more particular characteristics). The debug tree in FIG. 4 may be used to search new errors to determine if the cause of the error is captured by the nodes of the tree (e.g., nodes from the root to another one or more nodes in the tree will return TRUE).

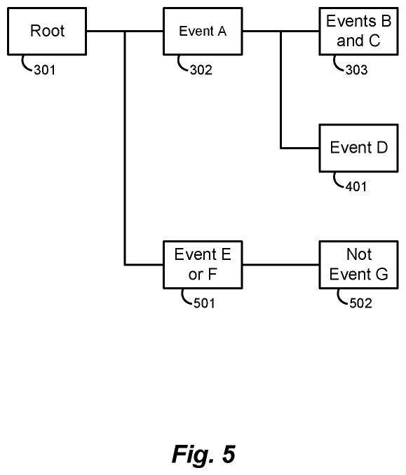

FIG. 5 illustrates yet another example of node creation during debug according to an embodiment. FIG. 5 includes the occurrence of a newly observed test failure. Here, the newly observed event produced a FALSE for nodes 302, 303 and 401, and two (2) new nodes 501 and 502 are added to the debug tree to capture the failure. Node 501 corresponds to either event E or event F happening, and node 502 corresponds to event G not happening. Accordingly, nodes 501 and 502 illustrate how multiple event occurrences can be used to define a node and how the non-occurrence of an event can define a node. Parameter values for node 501 may be as follows: [log file path: <path>; regular expression 1: <regular expression describing event E>; regular expression 2: <regular expression describing event F>; regular expression match type: ANY; search direction: FORWARD; start time: “previous node time”; return value if regular expression not found: FALSE]. Parameter values for node 502 may be as follows: [log file path: <fsdb_log_path>; signal, value, bit range: “[signal_for_event_G]”; search direction: FORWARD; start time: “previous node time”; and return value if regular expression not found: TRUE].

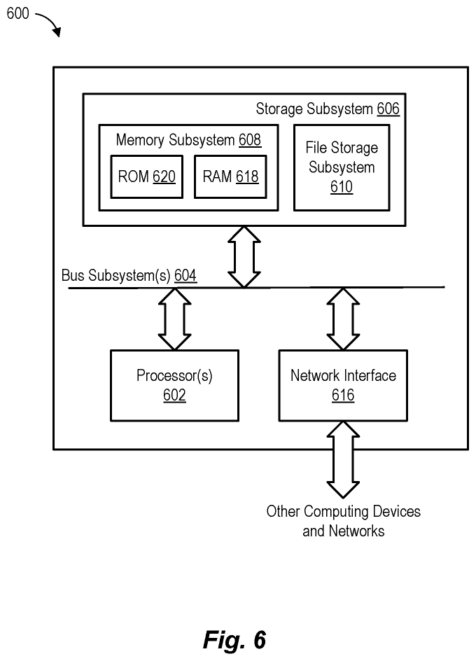

FIG. 6 depicts a simplified block diagram of an example computer system 600, which can be used to implement some of the techniques described in the foregoing disclosure. As shown in FIG. 6, system 600 includes one or more processors 602 that communicate with a number of devices via one or more bus subsystems 604. These devices may include a storage subsystem 606 (e.g., comprising a memory subsystem 608 and a file storage subsystem 610) and a network interface subsystem 616. Some systems may further include user interface input devices and/or user interface output devices (not shown).

Bus subsystem 604 can provide a mechanism for letting the various components and subsystems of system 600 communicate with each other as intended. Although bus subsystem 604 is shown schematically as a single bus, alternative embodiments of the bus subsystem can utilize multiple busses.

Network interface subsystem 616 can serve as an interface for communicating data between system 600 and other computer systems or networks. Embodiments of network interface subsystem 616 can include, e.g., Ethernet, a Wi-Fi and/or cellular adapter, a modem (telephone, satellite, cable, etc.), and/or the like.

Storage subsystem 606 includes a memory subsystem 608 and a file/disk storage subsystem 610. Subsystems 608 and 610 as well as other memories described herein are examples of non-transitory computer-readable storage media that can store executable program code and/or data that provide the functionality of embodiments of the present disclosure.

Memory subsystem 608 comprise one or more memories including a main random access memory (RAM) 618 for storage of instructions and data during program execution and a read-only memory (ROM) 620 in which fixed instructions are stored. File storage subsystem 610 can provide persistent (e.g., non-volatile) storage for program and data files, and can include a magnetic or solid-state hard disk drive, an optical drive along with associated removable media (e.g., CD-ROM, DVD, Blu-Ray, etc.), a removable flash memory-based drive or card, and/or other types of storage media known in the art.

| It should be appreciated that system 600 is illustrative and many other configurations having more or fewer components than system 600 are possible.

### Further Examples

Each of the following non-limiting features in the following examples may stand on its own or may be combined in various permutations or combinations with one or more of the other features in the examples below. In various embodiments, the present disclosure may be implemented as a processor or method.

In some embodiments the present disclosure includes a verification system comprising one or more processors and a non-transitory computer-readable medium storing a program executable by the one or more processors, the program comprising sets of instructions for performing the techniques described herein. In another embodiment, the present disclosure includes a verification method comprising steps to perform the techniques described herein. In yet another embodiment, the present disclosure includes a non-transitory computer-readable medium storing a program executable by one or more processors, the program comprising sets of instructions for performing the techniques described herein.

In some embodiments, the instructions and steps above comprising storing values for a plurality of parameters for a plurality of nodes of a debug tree, the debug tree comprising a root node and said plurality of nodes associated to the root node directly or through one or more other nodes, wherein the parameters specify events defining electronically stored errors in a system being verified, wherein each event corresponds to a particular node of the plurality of nodes of the debug tree; receiving an input specifying a first error in the system being verified; accessing one or more data sources using particular values for parameters associated with each node, the data sources comprising information describing errors generated by the system being verified corresponding to the events for the plurality of nodes; returning, for each node, information corresponding to the events; and determining, for each node, whether or not the first error matches events corresponding to the plurality of nodes.

In one embodiment, the parameters for at least one node comprise a first parameter to describe a path to at least one of the data sources and one or more second parameters describing one or more regular expressions for searching the at least one of the data sources.

In one embodiment, the one or more second parameters comprise a plurality of second parameters describing a plurality of regular expressions, the parameters for at least one node further comprising a parameter to describe a relationship between the plurality of second parameters.

In one embodiment, the parameters for at least one node comprise a parameter to a waveform event.

In one embodiment, the parameters for at least one node comprise a parameter specifying a temporal relationship between the at least one node to adjacent nodes in the debug tree.

In one embodiment, the parameters for at least one node comprise a parameter specifying a timeframe for a search.

In one embodiment, the system being verified is one of: a software system and a high level definition of an electronic system.

In one embodiment, when the input matches at least a first portion of said events and the input does not match a second portion of said events corresponding to the plurality of nodes, and further comprising instructions for: prompting a user to define a new event for a new node of the debug tree, wherein the user specifies new values for said parameters for the new node of the debug tree.

In one embodiment, the system being verified is a high level definition (HDL) of an electronic system, and wherein at least one of the parameters specifies whether the new event occur before or after another event corresponding to another node of the debug tree.

In one embodiment, the root node is associated with context for said accessing and determining steps, the context comprising information specifying one or more of: database sources, log files, stored RTL signals, parameters for a test bench, and custom debug functions.

In one embodiment, the instructions or steps further comprising instructions or steps for receiving a first program code for generating the debug tree and a second program code for accessing the one or more data sources using the particular values for the parameters associated with each node, wherein the first program code and second program code are compiled into said program to perform said accessing, returning, and determining steps.

In one embodiment, the debug tree describes a set of observable events that associate an electronically recorded failure to a root cause.

The above description illustrates various embodiments along with examples of how aspects of some embodiments may be implemented. The above examples and embodiments should not be deemed to be the only embodiments, and are presented to illustrate the flexibility and advantages of some embodiments as defined by the following claims. Based on the above disclosure and the following claims, other arrangements, embodiments, implementations and equivalents may be employed without departing from the scope hereof as defined by the claims.

What is claimed is:

1. A verification system comprising:
one or more processors;
a non-transitory computer-readable medium storing a program executable by the one or more processors, the program comprising sets of instructions for:
storing values for a plurality of parameters for a plurality of nodes of a debug tree, the debug tree comprising a root node and said plurality of nodes associated to the root node directly or through one or more other nodes, wherein the parameters specify events defining electronically stored errors in a system being verified, wherein each event corresponds to a particular node of the plurality of nodes of the debug tree;
receiving an input specifying a first error in the system being verified;
accessing one or more data sources using particular values for parameters associated with each node, the data sources comprising information describing errors generated by the system being verified corresponding to the events for the plurality of nodes;
returning, for each node, information corresponding to the events; and
determining, for each node, whether or not the first error matches events corresponding to the plurality of nodes.

2. The verification system of claim 1, wherein the parameters for at least one node comprise a first parameter to describe a path to at least one of the data sources and one or more second parameters describing one or more regular expressions for searching the at least one of the data sources.

3. The verification system of claim 2, wherein the one or more second parameters comprise a plurality of second parameters describing a plurality of regular expressions, the parameters for at least one node further comprising a parameter to describe a relationship between the plurality of second parameters.

4. The verification system of claim 1, wherein the parameters for at least one node comprise a parameter to a waveform event.

5. The verification system of claim 1, wherein the parameters for at least one node comprise a parameter specifying a temporal relationship between the at least one node to adjacent nodes in the debug tree.

6. The verification system of claim 1, wherein the parameters for at least one node comprise a parameter specifying a timeframe for a search.

7. The verification system of claim 1, wherein the system being verified is one of: a software system and a high level definition of an electronic system.

8. The verification system of claim 1, wherein when the input matches at least a first portion of said events and the input does not match a second portion of said events corresponding to the plurality of nodes, and further comprising instructions for:
prompting a user to define a new event for a new node of the debug tree, wherein the user specifies new values for said parameters for the new node of the debug tree.

9. The verification system of claim 8, wherein the system being verified is a high level definition (HDL) of an electronic system, and wherein at least one of the parameters specifies whether the new event occur before or after another event corresponding to another node of the debug tree.

10. The verification system of claim 1, wherein the root node is associated with context for said accessing and determining steps, the context comprising information specifying one or more of: database sources, log files, stored RTL signals, parameters for a test bench, and custom debug functions.

11. The verification system of claim 1, further comprising instructions for receiving a first program code for generating the debug tree and a second program code for accessing the one or more data sources using the particular values for the parameters associated with each node, wherein the first program code and second program code are compiled into said program to perform said accessing, returning, and determining steps.

12. The verification system of claim 1, wherein the debug tree describes a set of observable events that associate an electronically recorded failure to a root cause.

13. A verification method comprising:
storing values for a plurality of parameters for a plurality of nodes of a debug tree, the debug tree comprising a root node and said plurality of nodes associated to the root node directly or through one or more other nodes, wherein the parameters specify events defining electronically stored errors in a system being verified, wherein each event corresponds to a particular node of the plurality of nodes of the debug tree;
receiving an input specifying a first error in the system being verified;
accessing one or more data sources using particular values for parameters associated with each node, the data sources comprising information describing errors generated by the system being verified corresponding to the events for the plurality of nodes;
returning, for each node, information corresponding to the events; and
determining, for each node, whether or not the first error matches events corresponding to the plurality of nodes.

14. The method of claim 13, wherein the parameters for at least one node comprise a first parameter to describe a path to at least one of the data sources and one or more second parameters describing one or more regular expressions for searching the at least one of the data sources.

15. The method of claim 13, wherein the parameters for at least one node comprise a parameter specifying a temporal relationship between the at least one node to adjacent nodes in the debug tree.

16. The method of claim 13, wherein the parameters for at least one node comprise a parameter to a waveform event.

17. A non-transitory computer-readable medium storing a program executable by one or more processors, the program comprising sets of instructions for:
storing values for a plurality of parameters for a plurality of nodes of a debug tree, the debug tree comprising a root node and said plurality of nodes associated to the root node directly or through one or more other nodes, wherein the parameters specify events defining electronically stored errors in a system being verified, wherein each event corresponds to a particular node of the plurality of nodes of the debug tree;
receiving an input specifying a first error in the system being verified;
accessing one or more data sources using particular values for parameters associated with each node, the data sources comprising information describing errors generated by the system being verified corresponding to the events for the plurality of nodes;
returning, for each node, information corresponding to the events; and
determining, for each node, whether or not the first error matches events corresponding to the plurality of nodes.

18. The computer readable medium of claim 17, wherein the parameters for at least one node comprise a first parameter to describe a path to at least one of the data sources and one or more second parameters describing one or more regular expressions for searching the at least one of the data sources.

19. The computer readable medium of claim 17, wherein the parameters for at least one node comprise a parameter specifying a temporal relationship between the at least one node to adjacent nodes in the debug tree.

20. The computer readable medium of claim 17, wherein the parameters for at least one node comprise a parameter to a waveform event.
